(19) United States
(12) Patent Application Publication
(10) Pub. No.: US 2017/0286250 A1
(43) Pub. Date: Oct. 5, 2017

(54) Signal Compensation Method and Device

(71) Applicant: Huawei Technologies Co., Ltd., Shenzhen (CN)

(72) Inventors: Wei Chen, Shenzhen (CN); Jiangwei Man, Wuhan (CN); Li Zeng, Shenzhen (CN)

(21) Appl. No.: 15/631,869

(22) Filed: Jun. 23, 2017

Related U.S. Application Data
(63) Continuation of application No. PCT/CN2014/095111, filed on Dec. 26, 2014.

(51) Int. Cl. H04B 10/69; H04B 3/23; H03M 13/25; G01R 31/30; H04L 25/03

(52) U.S. Cl. CPC G06F 11/34; G01R 31/3004; G01R 31/3016; H04L 25/03038; H04L 25/03057; H03M 13/256; H04B 3/23

(57) ABSTRACT

A signal compensation method and device, where the method includes receiving a signal sequence suffering from intersymbol interference (ISI), setting a first filtering coefficient to perform filter compensation on the received signal sequence to obtain a first compensation signal sequence, setting a balance filtering coefficient to perform filter compensation on the first compensation signal sequence to obtain a balance compensation result, where the balance filtering coefficient is obtained by adjusting, according to a first compensation error, a balance filtering coefficient set last time, performing sequence estimation on the balance compensation result and outputting the balance compensation result, where the first compensation error adjusts the balance filtering coefficient set to perform filter compensation on the first compensation signal sequence in an iterative manner, thereby effectively compensating for the signal sequence suffering from the ISI, and improving performance of an optical fiber communications system.

### CROSS-REFERENCE TO RELATED APPLICATION

This application is a continuation of International Patent Application No. PCT/CN2014/095111 filed on Dec. 26, 2014, which is hereby incorporated by reference in its entirety.

### TECHNICAL FIELD

The present application relates to the field of optical communications technologies, and in particular, to a signal compensation method and device.

### BACKGROUND

In a development process of communications technologies, much work has been done to increase an information transmission rate and distance and improve availability, reliability, and cost-effectiveness of a communications system, and remarkable achievements have been made. As a latest achievement in the development of modern communications technologies, an optical communications technology has become a cornerstone of modern communications, and is a main transfer tool of various types of information in a future information society.

An optical fiber is used as a communication channel to constitute an optical fiber communications system. In addition to characteristics of a wide transmission frequency band, a large communication capacity, a small transmission loss, a long trunk distance, and a strong anti-electromagnetic interference capability of the optical fiber communications system, loss and dispersion are most important transmission characteristics of the optical fiber and are also basic problems of the optical fiber communications system.

Due to existence of dispersion, a broadening phenomenon occurs on an optical pulse during transmission on an optical fiber channel. The pulse broadening causes intersymbol interference (ISI) between adjacent pulses. This shortens a transmission distance and increases a bit error rate of the system, thereby decreasing performance of the optical fiber communications system.

To reduce or eliminate impact of the ISI on channel performance, a signal bandwidth compensation mechanism is proposed. The compensation mechanism further includes feed-forward equalization (FFE), decision-feedback equalization (DFE), and maximum-likelihood sequence equalization (MLSE). The FFE is used to pre-compensate for a system loss, the DEF is used to generate controllable ISI, and the MLSE is used to compensate for the generated controllable ISI, thereby improving the performance of the optical fiber communications system.

However, the foregoing compensation mechanism has the following disadvantage. Filtering coefficient balance is performed only on the FFE and the DFE during system compensation, and as a result, improving the performance of the optical fiber communications system using the compensation mechanism cannot satisfy people's requirements for the performance of the optical fiber communications system.

### SUMMARY

In view of this, embodiments of the present disclosure provide a signal compensation method and device in order to resolve a problem that an existing compensation mechanism does not greatly improve performance of an optical fiber communications system.

According to a first aspect, a signal compensation device is provided, including a first compensation module, a balance filtering module, and a second compensation module, where the first compensation module is configured to receive an input signal sequence suffering from ISI, set a first filtering coefficient to perform filtering compensation on the received signal sequence in order to obtain a first compensation signal sequence, the balance filtering module is configured to set a balance filtering coefficient to perform filtering compensation on the first compensation signal sequence in order to obtain a balance compensation result, where the balance filtering coefficient is obtained by adjusting, according to a first compensation error sent by the second compensation module, a balance filtering coefficient used last time, and the second compensation module is configured to perform sequence estimation on the balance compensation result and output the balance compensation result, obtain the first compensation error by means of calculation according to a compensation error value obtained last time by means of calculation and a compensation error value obtained the last but one time by means of calculation, and send the first compensation error to the balance filtering module.

With reference to the first aspect, in a first possible implementation, the second compensation module is further configured to perform subtraction on the compensation error value obtained last time by means of calculation and the compensation error value obtained the last but one time by means of calculation, where a difference obtained is the first compensation error.

With reference to the first aspect, or with reference to the first possible implementation of the first aspect, in a second possible implementation, the second compensation module is further configured to calculate a compensation error value of the currently received balance compensation result when receiving the balance compensation result from the balance filtering module, and obtain a second compensation error by means of calculation according to the compensation error value obtained last time by means of calculation and the compensation error value of the currently received balance compensation result, and send the second compensation error obtained by means of calculation to the balance filtering module.

With reference to the first aspect, or with reference to the first possible implementation of the first aspect, or with reference to the second possible implementation of the first aspect, in a third possible implementation, the balance filtering module is further configured to obtain the j^{th} balance filtering coefficient in the following manner:

b_{j(current)}=b_{j(last time)}+μ*sign(e_{last but one time}−e_{last time}),

where b_{j(current)} is an obtained coefficient weight of the j^{th} balance filtering coefficient that is currently set, a value range of j is 0 to L_{b}, L_{b} is a length of the balance filtering coefficient, b_{j(last time)} is a basic coefficient weight of the j^{th} balance filtering coefficient set last time, μ is a coefficient change length of the balance filtering coefficient, e_{last but one time}−e_{last time} is the first compensation error, e_{last but one time} is the compensation error value obtained the last but one time by means of calculation, and e_{last time} is the compensation error value obtained last time by means of calculation.

With reference to the first aspect, or with reference to the first possible implementation of the first aspect, or with reference to the second possible implementation of the first aspect, or with reference to the third possible implementation of the first aspect, in a fourth possible implementation, the first compensation module is further configured to send, at an initialization stage, the first filtering coefficient to the balance filtering module, and the balance filtering module is further configured to receive the first filtering coefficient sent by the first compensation module, determine, according to a coefficient weight of the first filtering coefficient, a basic coefficient weight of an initialized balance filtering coefficient set by the balance filtering module, and obtain an initial value of the balance filtering coefficient according to the basic coefficient weight of the initialized balance filtering coefficient set by the balance filtering module.

With reference to the fourth possible implementation of the first aspect, in a fifth possible implementation, if the received first filtering coefficient sent by the first compensation module is

$$F ( z ) = {\sum }_{i = 0}^{{L}_{f}} {f}_{i} {z}^{- i} ,$$

the balance filtering module is further configured to determine, according to the coefficient weight of the first filtering coefficient and in the following manner, the basic coefficient weight of the initialized balance filtering coefficient set by the balance filtering module:

b₀f₀; bⱼ=−fᵢ,

where bⱼ is a basic coefficient weight of the j^{th} balance filtering coefficient that is initialized, the value range of j is 0 to L_{b}, L_{b} is the length of the balance filtering coefficient, f is a coefficient weight of the j^{th} first filtering coefficient, a value range of i is 0 to L_{f}, and L_{f} is a length of the first filtering coefficient.

With reference to the first aspect, or with reference to the first possible implementation of the first aspect, or with reference to the second possible implementation of the first aspect, or with reference to the third possible implementation of the first aspect, or with reference to the fourth possible implementation of the first aspect, or with reference to the fifth possible implementation of the first aspect, in a sixth possible implementation, the first compensation module is further configured to calculate an error result according to a first compensation signal sequence obtained last time and a decision value of the first compensation signal sequence obtained last time, adjust the first filtering coefficient according to the error result obtained by means of calculation, and set an adjusted first filtering coefficient to perform filtering compensation on the currently received signal sequence.

According to a second aspect, a signal compensation method is provided, including receiving an input signal sequence suffering from ISI, and setting a first filtering coefficient to perform filtering compensation on the received signal sequence in order to obtain a first compensation signal sequence, setting a balance filtering coefficient to perform filtering compensation on the first compensation signal sequence in order to obtain a balance compensation result, where the balance filtering coefficient is obtained by adjusting, according to a first compensation error, a balance filtering coefficient set last time, and the first compensation error is obtained by means of calculation according to a compensation error value obtained last time by means of calculation and a compensation error value obtained the last but one time by means of calculation, and performing sequence estimation on the obtained balance compensation result and outputting the balance compensation result.

With reference to the second aspect, in a first possible implementation, that the first compensation error is obtained by means of calculation according to a compensation error value obtained last time by means of calculation and a compensation error value obtained the last but one time by means of calculation includes performing subtraction on the compensation error value obtained last time by means of calculation and the compensation error value obtained the last but one time by means of calculation, where a difference obtained is the first compensation error.

With reference to the second aspect, or with reference to the first possible implementations of the second aspect, in a second possible implementation, the method further includes calculating a compensation error value of the currently received balance compensation result when obtaining the balance compensation result, and obtaining a second compensation error by means of calculation according to the compensation error value obtained last time by means of calculation and the compensation error value of the currently received balance compensation result, where the second compensation error is used to adjust a currently set balance filtering coefficient.

With reference to the second aspect, or with reference to the first possible implementation of the second aspect, or with reference to the second possible implementation of the second aspect, in a third possible implementation, the j^{th} balance filtering coefficient that is currently set is obtained in the following manner:

b_{j(current)}=b_{j(last time)}+μ*sign(e_{last but one time}−e_{last time}),

where b_{j(current)} is an obtained coefficient weight of the j^{th} balance filtering coefficient that is currently set, a value range of j is 0 to L_{b}, L_{b} is a length of the balance filtering coefficient, b_{j(last time)} is a basic coefficient weight of the j^{th} balance filtering coefficient set last time, μ is a coefficient change length of the balance filtering coefficient, e_{last but one time}−e_{last time} is the first compensation error, e_{last but one time} is the compensation error value obtained the last but one time by means of calculation, and e_{last time} is the compensation error value obtained last time by means of calculation.

With reference to the second aspect, or with reference to the first possible implementation of the second aspect, or with reference to the second possible implementation of the second aspect, or with reference to the third possible implementation of the second aspect, in a fourth possible implementation, the method further includes determining, at an initialization stage, a basic coefficient weight of an initialized balance filtering coefficient according to a coefficient weight of the first filtering coefficient, and obtaining an initial value of the balance filtering coefficient according to the basic coefficient weight of the initialized balance filtering coefficient.

With reference to the fourth possible implementation of the second aspect, in a fifth possible implementation, if the first filtering coefficient is

$$F ( z ) = {\sum }_{i = 0}^{{L}_{f}} {f}_{i} {z}^{- i} ,$$

determining a basic coefficient weight of an initialized balance filtering coefficient according to a coefficient weight of the first filtering coefficient includes determining the basic coefficient weight of the initialized balance filtering coefficient in the following manner:

b₀f₀; bⱼ=−fᵢ,

where bⱼ is a basic coefficient weight of the j^{th} balance filtering coefficient that is initialized, the value range of j is 0 to L_{b}, L_{b} is the length of the balance filtering coefficient, f is a coefficient weight of the j^{th} first filtering coefficient, a value range of i is 0 to L_{f}, and L_{f} is a length of the first filtering coefficient.

With reference to the second aspect, or with reference to the first possible implementation of the second aspect, or with reference to the second possible implementation of the second aspect, or with reference to the third possible implementation of the second aspect, or with reference to the fourth possible implementation of the second aspect, or with reference to the fifth possible implementation of the second aspect, in a sixth possible implementation, the method further includes calculating an error result according to a first compensation signal sequence obtained last time and a decision value of the first compensation signal sequence obtained last time, and adjusting the first filtering coefficient according to the error result obtained by means of calculation, and setting a first filtering coefficient to perform filtering compensation on the received signal sequence in order to obtain a first compensation signal sequence includes setting an adjusted first filtering coefficient to perform filtering compensation on the currently received signal sequence in order to obtain the first compensation signal sequence.

According to a third aspect, a signal compensation device is provided, including a signal receiver configured to receive an input signal sequence suffering from ISI, a processor configured to set a first filtering coefficient to perform filtering compensation on the received signal sequence in order to obtain a first compensation signal sequence, and set a balance filtering coefficient to perform filtering compensation on the first compensation signal sequence in order to obtain a balance compensation result, where the balance filtering coefficient is obtained by adjusting, according to a first compensation error, a balance filtering coefficient set last time, and the first compensation error is obtained by means of calculation according to a compensation error value obtained last time by means of calculation and a compensation error value obtained the last but one time by means of calculation, and a signal transmitter configured to perform sequence estimation on the received balance compensation result and output the balance compensation result.

With reference to the third aspect, in a first possible implementation, that the first compensation error is obtained by means of calculation according to a compensation error value obtained last time by means of calculation and a compensation error value obtained the last but one time by means of calculation includes performing subtraction on the compensation error value obtained last time by means of calculation and the compensation error value obtained the last but one time by means of calculation, where a difference obtained is the first compensation error.

With reference to the third aspect, or with reference to the first possible implementation of the third aspect, in a second possible implementation, the processor is further configured to calculate a compensation error value of the currently received balance compensation result when obtaining the balance compensation result, and obtain a second compensation error by means of calculation according to the compensation error value obtained last time by means of calculation and the compensation error value of the currently received balance compensation result, where the second compensation error is used to adjust a currently set balance filtering coefficient.

With reference to the third aspect, or with reference to the first possible implementation of the third aspect, or with reference to the second possible implementation of the third aspect, in a third possible implementation, the processor obtains, in the following manner, the j^{th} balance filtering coefficient that is currently set:

b_{j(current)}=b_{j(last time)}+μ*sign(e_{last but one time}−e_{last time}),

where b_{j(current)} is an obtained coefficient weight of the j^{j} balance filtering coefficient that is currently set, a value range of j is 0 to L_{b}, L_{b} is a length of the balance filtering coefficient, b_{j(last time)} is a basic coefficient weight of the j^{th} balance filtering coefficient set last time, μ is a coefficient change length of the balance filtering coefficient, e_{last but one time}−e_{last time} is the first compensation error, e_{last but one time} is the compensation error value obtained the last but one time by means of calculation, and e_{last time} is the compensation error value obtained last time by means of calculation.

With reference to the third aspect, or with reference to the first possible implementation of the third aspect, or with reference to the second possible implementation of the third aspect, or with reference to the third possible implementation of the third aspect, in a fourth possible implementation, the processor is further configured to determine, at an initialization stage, a basic coefficient weight of an initialized balance filtering coefficient according to a coefficient weight of the first filtering coefficient, and obtain an initial value of the balance filtering coefficient according to the basic coefficient weight of the initialized balance filtering coefficient.

With reference to the fourth possible implementation of the third aspect, in a fifth possible implementation, if the first filtering coefficient is

$$F ( z ) = {\sum }_{i = 0}^{{L}_{f}} {f}_{i} {z}^{- i} ,$$

that the processor determines a basic coefficient weight of an initialized balance filtering coefficient according to a coefficient weight of the first filtering coefficient includes determining the basic coefficient weight of the initialized balance filtering coefficient in the following manner:

b₀f₀; bⱼ=−fᵢ,

where bⱼ is a basic coefficient weight of the j^{th} balance filtering coefficient that is initialized, the value range of j is 0 to L_{b}, L_{b} is the length of the balance filtering coefficient, f is a coefficient weight of the j^{th} first filtering coefficient, a value range of i is 0 to L_{f}, and L_{f} is a length of the first filtering coefficient.

With reference to the third aspect, or with reference to the first possible implementation of the third aspect, or with reference to the second possible implementation of the third aspect, or with reference to the third possible implementation of the third aspect, or with reference to the fourth possible implementation of the third aspect, or with reference to the fifth possible implementation of the third aspect, in a sixth possible implementation, the processor is further configured to calculate an error result according to a first compensation signal sequence obtained last time and a decision value of the first compensation signal sequence obtained last time, and adjust the first filtering coefficient according to the error result obtained by means of calculation, and set an adjusted first filtering coefficient to perform filtering compensation on the currently received signal sequence in order to obtain the first compensation signal sequence.

The embodiments of the present disclosure have the following beneficial effects.

According to the embodiments of the present disclosure, an input signal sequence suffering from ISI is received, and a first filtering coefficient is used to perform filtering compensation on the received signal sequence to obtain a first compensation signal sequence, a balance filtering coefficient is used to perform filtering compensation on the first compensation signal sequence to obtain a balance compensation result, where the balance filtering coefficient is obtained by adjusting, according to a first compensation error, a balance filtering coefficient set last time, and the first compensation error is obtained by means of calculation according to a compensation error value obtained last time by means of calculation and a compensation error value obtained the last but one time by means of calculation, and sequence estimation is performed on the received balance compensation result and the balance compensation result is output. A first compensation error is generated by a back-end compensation module, the first compensation error is used to adjust a balance filtering coefficient in an iterative manner, and an adjusted balance filtering coefficient is used to perform filtering compensation on a first compensation signal sequence, thereby balancing performance between compensation modules at various levels, effectively compensating for a signal sequence suffering from ISI, and improving performance of an optical fiber communications system.

### BRIEF DESCRIPTION OF DRAWINGS

To describe the technical solutions in the embodiments of the present disclosure more clearly, the following briefly describes the accompanying drawings required for describing the embodiments. The accompanying drawings in the following description show merely some embodiments of the present disclosure, and persons of ordinary skill in the art may still derive other drawings from these accompanying drawings without creative efforts.

FIG. 1 is a schematic structural diagram of a signal compensation device according to the present disclosure;

FIG. 2 is a schematic flowchart of a signal compensation method according to the present disclosure; and

FIG. 3 is a schematic structural diagram of a signal compensation device according to the present disclosure.

### DESCRIPTION OF EMBODIMENTS

To implement the objectives of the present disclosure, the embodiments of the present disclosure provide a signal compensation method and device. An input signal sequence suffering from ISI is received, and a first filtering coefficient is used to perform filtering compensation on the received signal sequence to obtain a first compensation signal sequence. A balance filtering coefficient is used to perform filtering compensation on the first compensation signal sequence to obtain a balance compensation result, where the balance filtering coefficient is obtained by adjusting, according to a first compensation error, a balance filtering coefficient set last time, and the first compensation error is obtained by means of calculation according to a compensation error value obtained last time by means of calculation and a compensation error value obtained the last but one time by means of calculation, and sequence estimation is performed on the received balance compensation result and the balance compensation result is output. A first compensation error is generated by a back-end compensation module, the first compensation error is used to adjust a balance filtering coefficient in an iterative manner, and an adjusted balance filtering coefficient is used to perform filtering compensation on a first compensation signal sequence, thereby balancing performance between compensation modules at various levels, effectively compensating for a signal sequence suffering from ISI, and improving performance of an optical fiber communications system.

The following further describes the embodiments of the present disclosure in detail with reference to this specification. The described embodiments are merely some but not all of the embodiments of the present disclosure. All other embodiments obtained by persons of ordinary skill in the art based on the embodiments of the present disclosure without creative efforts shall fall within the protection scope of the present disclosure.

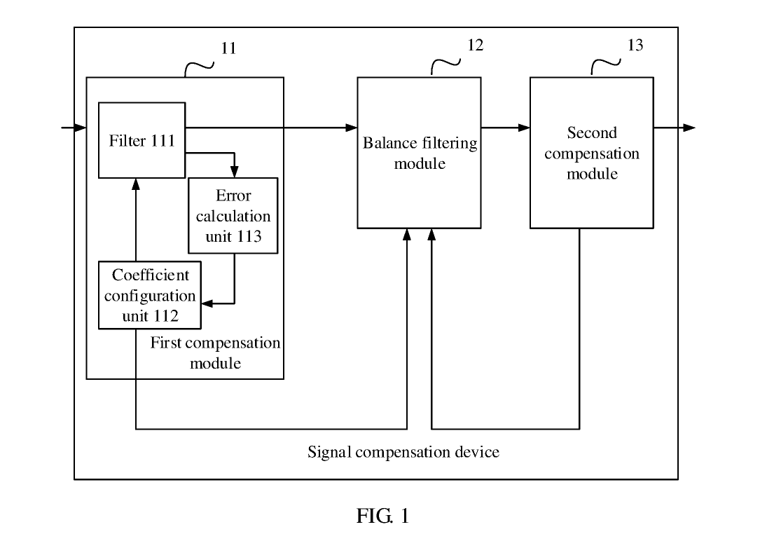

FIG. 1 is a schematic structural diagram of a signal compensation device according to an embodiment of the present disclosure. The signal compensation device includes a first compensation module 11, a balance filtering module 12, and a second compensation module 13.

The first compensation module 11 is configured to receive an input signal sequence suffering from ISI, set a first filtering coefficient to perform filtering compensation on the received signal sequence in order to obtain a first compensation signal sequence, and send the first compensation signal sequence to the balance filtering module 12.

The balance filtering module 12 is configured to set a balance filtering coefficient to perform filtering compensation on the first compensation signal sequence that is sent by the first compensation module 11 in order to obtain a balance compensation result, and send the balance compensation result to the second compensation module 13. The balance filtering coefficient is obtained by adjusting, according to a first compensation error sent by the second compensation module 13, a balance filtering coefficient set last time.

The second compensation module 13 is configured to receive the balance compensation result sent by the balance filtering module 12, perform sequence estimation on the received balance compensation result and output the balance compensation result, obtain the first compensation error by means of calculation according to a compensation error value obtained last time by means of calculation and a compensation error value obtained the last but one time by means of calculation, and send the first compensation error to the balance filtering module 12.

Optionally, the first compensation module 11 is further configured to calculate an error result according to a first compensation signal sequence obtained last time and a decision value of the first compensation signal sequence obtained last time, adjust the first filtering coefficient according to the error result obtained by means of calculation, and set an adjusted first filtering coefficient to perform filtering compensation on the currently received signal sequence.

It should be noted that the decision value of the first compensation signal sequence obtained last time refers to a value obtained after the first compensation signal sequence obtained last time is quantized.

Further, the first compensation module 11 may include a filter 111 and a coefficient configuration unit 112. Optionally, the first compensation module 11 may further include an error calculation unit 113.

The filter 111 is configured to receive the input signal sequence suffering from the ISI, set the first filtering coefficient configured by the coefficient configuration unit 112 in order to perform filtering compensation on the received signal sequence in order to obtain the first compensation signal sequence, and send the first compensation signal sequence to the balance filtering module 12.

For example, the received input signal sequence suffering from the ISI may be:

$${r}_{k} = {\sum }_{a = 0}^{{L}_{c}} {c}_{a} * {x}_{k - a} + {n}_{k} ,$$

where rₖ is the k^{th} signal, nₖ is noise of the k^{th} signal, cₐ is a coefficient to be compensated, a value range of a is 0 to L_{c}, L_{c} is a channel memory length, and x is a signal sequence.

The coefficient configuration unit 112 is adapted to configure the first filtering coefficient. An FFE structure or a DFE structure may be used. The first filtering coefficient is adaptively configured using a least mean square (LMS) algorithm or another algorithm.

For example, the first filtering coefficient is:

$$F ( z ) = {\sum }_{i = 0}^{{L}_{f}} {f}_{i} {z}^{- i} ,$$

where fᵢ is the i^{th} coefficient weight of the first filtering coefficient, a value range of i is 0 to L_{f}, L_{f} is a length of the first filtering coefficient, and z is any complex number.

It should be noted that in order to achieve a good compensation effect, L_{f} is generally required to be greater than or equal to L_{c}.

The coefficient configuration unit 112 herein may be adapted to configure an initial first filtering coefficient. The first filtering coefficient obtained afterwards is obtained by means of adjustment according to the error result sent by the error calculation unit 113.

The error calculation unit 113 is configured to calculate the error result according to the first compensation signal sequence obtained last time and the decision value of the first compensation signal sequence obtained last time, and send the error result to the coefficient configuration unit 112.

The coefficient configuration unit 112 is further configured to adjust the first filtering coefficient according to the error result sent by the error calculation unit 113, and send the adjusted first filtering coefficient to the filter 111.

It should be noted that the signal compensation device recorded in this embodiment of the present disclosure is a cyclic execution device. After the second compensation module 13 sends a second compensation error obtained by means of calculation to the balance filtering module 12, the balance filtering module 12 may set the second compensation error to adjust the balance filtering coefficient in order to perform filtering compensation when receiving the first compensation signal sequence sent by the first compensation module 11.

Therefore, the second compensation module 13 adjusts, according to a difference between compensation error values obtained two consecutive times by means of calculation, the balance filtering coefficient set by the balance filtering module 12 in order to achieve a purpose of balancing performance of various compensation modules.

The second compensation module 13 is further configured to perform subtraction on the compensation error value obtained last time by means of calculation and the compensation error value obtained the last but one time by means of calculation. A difference obtained is the first compensation error.

Optionally, the second compensation module 13 is further configured to calculate a compensation error value of the currently received balance compensation result when receiving the balance compensation result sent by the balance filtering module 12, obtain the second compensation error by means of calculation according to the compensation error value obtained last time by means of calculation and the compensation error value of the currently received balance compensation result, and send the second compensation error obtained by means of calculation to the balance filtering module 12.

The balance filtering module 12 is further configured to obtain the j^{th} balance filtering coefficient in the following manner:

b_{j(current)}=b_{j(last time)}+μ*sign(e_{last but one time}−e_{last time}),

where b_{j(current)} is an obtained coefficient weight of the j^{j} balance filtering coefficient that is currently set, a value range of j is 0 to L_{b}, L_{b} is a length of the balance filtering coefficient, b_{j(last time)} is a basic coefficient weight of the j^{th} balance filtering coefficient set last time, μ is a coefficient change length of the balance filtering coefficient, e_{last but one time}−e_{last time} is the first compensation error, e_{last but one time} is the compensation error value obtained the last but one time by means of calculation, and e_{last time} is the compensation error value obtained last time by means of calculation.

It should be noted that the first compensation module 11 is further configured to send, at an initialization stage, the first filtering coefficient to the balance filtering module 12.

The balance filtering module 12 is further configured to receive the first filtering coefficient sent by the first compensation module 11, determine, according to a coefficient weight of the first filtering coefficient, a basic coefficient weight of an initialized balance filtering coefficient set by the balance filtering module 12, and obtain an initial value of the balance filtering coefficient according to the basic coefficient weight of the initialized balance filtering coefficient set by the balance filtering module 12.

If the received first filtering coefficient from the first compensation module 11 is

$$F ( z ) = {\sum }_{i = 0}^{{L}_{f}} {f}_{i} {z}^{- i} ,$$

the balance filtering module 12 is further configured to determine, according to the coefficient weight of the first filtering coefficient and in the following manner, the basic coefficient weight of the initialized balance filtering coefficient set by the balance filtering module 12:

b₀f₀; bⱼ=−fᵢ,

where bⱼ is a basic coefficient weight of the j^{th} balance filtering coefficient that is initialized, the value range of j is 0 to L_{b}, L_{b} is the length of the balance filtering coefficient, f is a coefficient weight of the j^{th} first filtering coefficient, the value range of i is 0 to L_{f}, and L_{f} is the length of the first filtering coefficient.

The balance filtering module 12 is further configured to obtain the balance filtering coefficient according to a coefficient weight of a balance filtering coefficient obtained by means of adjustment, for example, the obtained balance filtering coefficient is:

$$B ( z ) = {\sum }_{j = 0}^{{L}_{b}} {b}_{j} * {z}^{- j} ,$$

where bⱼ is a coefficient weight of the balance filtering coefficient obtained by means of adjustment, the value range of j is 0 to L_{b}, and L_{b} is the length of the balance filtering coefficient.

The signal compensation device described in this embodiment of the present disclosure may be implemented by means of hardware, or may be implemented by means of software. No limitation is imposed herein. A first compensation error is generated by a back-end compensation module, the first compensation error is used to adjust a balance filtering coefficient in an iterative manner, and an adjusted balance filtering coefficient is used to perform filtering compensation on a first compensation signal sequence, thereby balancing performance between compensation modules at various levels, effectively compensating for a signal sequence suffering from ISI, and improving performance of an optical fiber communications system.

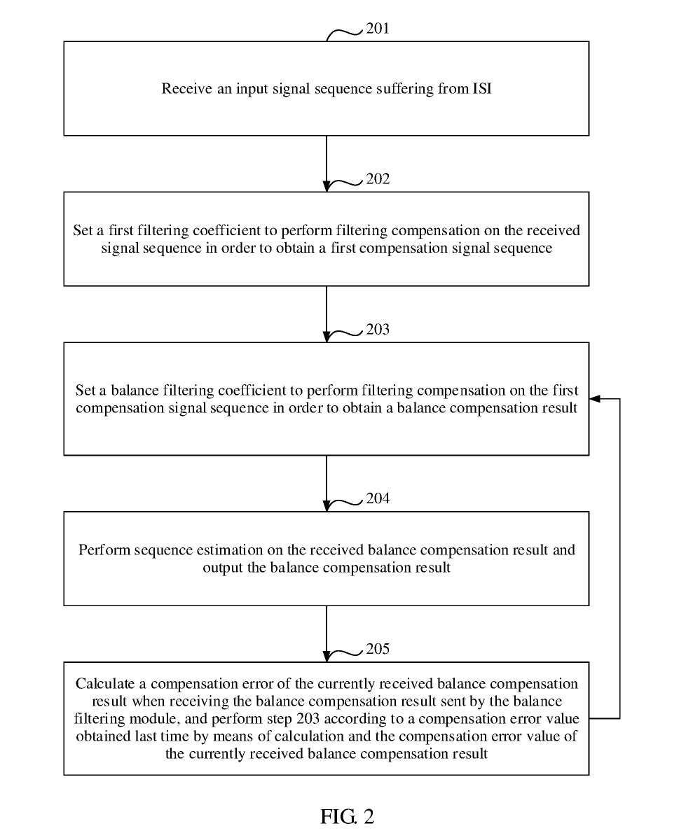

FIG. 2 is a schematic flowchart of a signal compensation method according to an embodiment of the present disclosure. The method may be described as follows.

Step 201: Receive an input signal sequence suffering from ISI.

In step 201, on an optical fiber communication link, ISI may easily occur on a communication signal. For example, due to a bandwidth limitation of a photoelectric transmitter or an electro-optic receiver, and the like, ISI occurs on a communication signal.

It is assumed that the received signal sequence suffering from the ISI is:

$${r}_{k} = {\sum }_{a = 0}^{{L}_{c}} {c}_{a} * {x}_{k - a} + {n}_{k} ,$$

where rₖ is the k^{th} signal, nₖ is noise of the k^{th} signal, cₐ is a coefficient to be compensated, a value range of a is 0 to L_{c}, L_{c} is a channel memory length, and x is a signal sequence.

Step 202: Set a first filtering coefficient to perform filtering compensation on the received signal sequence in order to obtain a first compensation signal sequence.

In step 202, the first filtering coefficient may be an initially configured filtering coefficient, or may be obtained by adjusting, according to a feedback, a filtering coefficient set last time.

If the first filtering coefficient is obtained by means of configuration, an FFE structure or a DFE structure may be set. The first filtering coefficient is adaptively configured using an LMS algorithm or another algorithm.

For example, the first filtering coefficient is:

$$F ( z ) = {\sum }_{i = 0}^{{L}_{f}} {f}_{i} {z}^{- i} ,$$

where fᵢ is the i^{th} coefficient weight of the first filtering coefficient, a value range of i is 0 to L_{f}, and L _{f} is a length of the first filtering coefficient.

It should be noted that in order to achieve a good compensation effect, L_{f} is generally required to be greater than or equal to L_{c}.

If the first filtering coefficient is obtained by adjusting, according to an error result that is fed back, the filtering coefficient set last time, the method further includes calculating the error result according to a first compensation signal sequence obtained last time and a decision value of the first compensation signal sequence obtained last time, and obtaining an adjusted first filtering coefficient by adjusting the first filtering coefficient (that is, the filtering coefficient set last time) according to the error result obtained by means of calculation.

Step 203: Set a balance filtering coefficient to perform filtering compensation on the first compensation signal sequence in order to obtain a balance compensation result.

The balance filtering coefficient is obtained by adjusting, according to a first compensation error, a balance filtering coefficient set last time, and the first compensation error is obtained by means of calculation according to a compensation error value obtained last time by means of calculation and a compensation error value obtained the last but one time by means of calculation.

In step 203, the j^{th} balance filtering coefficient that is currently set is obtained in the following manner:

b_{j(current)}=b_{j(last time)}+μ*sign(e_{last but one time}−e_{last time}),

where b_{j(current)} is an obtained coefficient weight of the j^{j} balance filtering coefficient that is currently set, a value range of j is 0 to L_{b}, L_{b} is a length of the balance filtering coefficient, b_{j(last time)} is a basic coefficient weight of the j^{th} balance filtering coefficient set last time, μ is a coefficient change length of the balance filtering coefficient, e_{last but one time}−e_{last time} is the first compensation error, e_{last but one time} is the compensation error value obtained the last but one time by means of calculation, and e_{last time} is the compensation error value obtained last time by means of calculation.

That is, the balance filtering coefficient is obtained in an iterative manner.

Therefore, an initial value of the balance filtering coefficient is determined in the manner of determining, at an initialization stage, a basic coefficient weight of an initialized balance filtering coefficient according to a coefficient weight of the first filtering coefficient, and obtaining the initial value of the balance filtering coefficient according to the basic coefficient weight of the initialized balance filtering coefficient.

Further, if the first filtering coefficient is

$$F ( z ) = {\sum }_{i = 0}^{{L}_{f}} {f}_{i} {z}^{- i} ,$$

the basic coefficient weight of the initialized balance filtering coefficient is determined in the following manner:

b₀f₀; bⱼ=−fᵢ,

where bⱼ is a basic coefficient weight of the j^{th} balance filtering coefficient that is initialized, the value range of j is 0 to L_{b}, L_{b} is the length of the balance filtering coefficient, f is a coefficient weight of the j^{th} first filtering coefficient, the value range of i is 0 to L_{f}, and L_{f} is the length of the first filtering coefficient.

Step 204: Perform sequence estimation on the received balance compensation result and output the balance compensation result.

Step 205: Calculate a compensation error of the currently received balance compensation result when receiving the balance compensation result sent by the balance filtering module, and perform step 203 according to a compensation error value obtained last time by means of calculation and the compensation error value of the currently received balance compensation result.

A second compensation error is set to adjust a currently set balance filtering coefficient.

In step 205, subtraction is performed on the compensation error value obtained last time by means of calculation and the compensation error value of the currently received balance compensation result, and a difference obtained is the second compensation error.

It should be noted that the operation performed in step 205 is a feedback operation. A balance filtering coefficient set by the balance filtering module is adjusted according to an error between two adjacent balance compensation results in order to achieve a purpose of balancing performance of various compensation modules.

According to the description in this embodiment of the present disclosure, an input signal sequence suffering from ISI is received, and a first filtering coefficient is used to perform filtering compensation on the received signal sequence to obtain a first compensation signal sequence. A balance filtering coefficient is used to perform filtering compensation on the first compensation signal sequence to obtain a balance compensation result, where the balance filtering coefficient is obtained by adjusting, according to a first compensation error, a balance filtering coefficient used last time, and the first compensation error is obtained by means of calculation according to a compensation error value obtained last time by means of calculation and a compensation error value obtained the last but one time by means of calculation, and sequence estimation is performed on the received balance compensation result and the balance compensation result is output. A first compensation error is generated by a back-end compensation module, the first compensation error is used to adjust a balance filtering coefficient in an iterative manner, and an adjusted balance filtering coefficient is used to perform filtering compensation on a first compensation signal sequence, thereby balancing performance between compensation modules at various levels, effectively compensating for a signal sequence suffering from ISI, and improving performance of an optical fiber communications system.

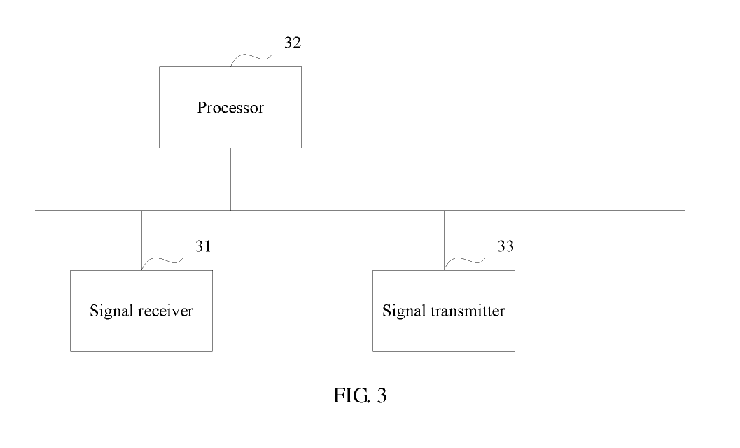

FIG. 3 is a schematic structural diagram of a signal compensation device according to an embodiment of the present disclosure. The signal compensation device has the foregoing signal compensation function, and may use a general computer structure. The signal compensation device entity may include a signal receiver 31, a processor 32, and a signal transmitter 33.

The signal receiver 31 is configured to receive an input signal sequence suffering from ISI.

The processor 32 is configured to set a first filtering coefficient to perform filtering compensation on the received signal sequence in order to obtain a first compensation signal sequence, and set a balance filtering coefficient to perform filtering compensation on the first compensation signal sequence in order to obtain a balance compensation result. The balance filtering coefficient is obtained by adjusting, according to a first compensation error, a balance filtering coefficient set last time, and the first compensation error is obtained by means of calculation according to a compensation error value obtained last time by means of calculation and a compensation error value obtained the last but one time by means of calculation.

The signal transmitter 33 is configured to perform sequence estimation on the received balance compensation result and output the balance compensation result.

Further, that the processor 32 is obtained by means of calculation according to a compensation error value obtained last time by means of calculation and a compensation error value obtained the last but one time by means of calculation includes performing subtraction on the compensation error value obtained last time by means of calculation and the compensation error value obtained the last but one time by means of calculation, where a difference obtained is the first compensation error.

The processor 32 is further configured to calculate a compensation error value of the currently received balance compensation result when obtaining the balance compensation result, and obtain a second compensation error by means of calculation according to the compensation error value obtained last time by means of calculation and the compensation error value of the currently obtained balance compensation result, where the second compensation error is used to adjust a currently set balance filtering coefficient.

Further, the processor 32 obtains, in the following manner, the j^{th} balance filtering coefficient that is currently set:

b_{j(current)}=b_{j(last time)}+μ*sign(e_{last but one time}−e_{last time}),

where b_{j(current)} is an obtained coefficient weight of the j^{j} balance filtering coefficient that is currently set, a value range of j is 0 to L_{b}, L_{b} is a length of the balance filtering coefficient, b_{j(last time)} is a basic coefficient weight of the j^{th} balance filtering coefficient set last time, μ is a coefficient change length of the balance filtering coefficient, e_{last but one time}−e_{last time} is the first compensation error, e_{last but one time} is the compensation error value obtained the last but one time by means of calculation, and e_{last time} is the compensation error value obtained last time by means of calculation.

The processor 32 is further configured to determine, at an initialization stage, a basic coefficient weight of an initialized balance filtering coefficient according to a coefficient weight of the first filtering coefficient, and obtain an initial value of the balance filtering coefficient according to the basic coefficient weight of the initialized balance filtering coefficient.

Further, if the first filtering coefficient is

$$F ( z ) = {\sum }_{i = 0}^{{L}_{f}} {f}_{i} {z}^{- i} ,$$

the processor 32 determining a basic coefficient weight of an initialized balance filtering coefficient according to a coefficient weight of the first filtering coefficient includes determining the basic coefficient weight of the initialized balance filtering coefficient in the following manner:

b₀f₀; bⱼ=−fᵢ,

where bⱼ is a basic coefficient weight of the j^{th} balance filtering coefficient that is initialized, the value range of j is 0 to L_{b}, L_{b} is the length of the balance filtering coefficient, fᵢ is a coefficient weight of the j^{th} first filtering coefficient, a value range of i is 0 to L_{f}, and L_{f} is a length of the first filtering coefficient.

The processor 32 is further configured to calculate an error result according to a first compensation signal sequence obtained last time and a decision value of the first compensation signal sequence obtained last time, and adjust the first filtering coefficient according to the error result obtained by means of calculation, and set an adjusted first filtering coefficient to perform filtering compensation on the currently received signal sequence in order to obtain the first compensation signal sequence.

The processor 32 may be a general processor, including a central processing unit (CPU), a network processor (NP), and the like, or may be a combination of a CPU and a hardware chip. The processor 32 may also be a digital signal processor (DSP), an application specific integrated circuit (ASIC), a field-programmable gate array (FPGA) or any other programmable logic device, a discrete gate or transistor logic device, or a discrete hardware component.

Persons of ordinary skill in the art may understand that all or a part of the steps in each of the foregoing method of the embodiments may be implemented by a program instructing a processor. The foregoing program may be stored in a computer readable storage medium. The storage medium may be a non-transitory medium, such as a random-access memory (RAM), read-only memory (ROM), a flash memory, a hard disk, a solid state drive, a magnetic tape, a floppy disk, an optical disc, or any combination thereof.

The present disclosure is described with reference to the flowcharts and/or block diagrams of the method, the device, and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine such that the instructions executed by a computer or a processor of any other programmable data processing device generate an apparatus for implementing a specific function in one or more processes in the flowcharts and/or in one or more blocks in the block diagrams.

The foregoing descriptions are merely examples of specific implementations of the present disclosure, but are not intended to limit the protection scope of the present disclosure. Any variation or replacement readily figured out by persons skilled in the art within the technical scope disclosed in the present disclosure shall fall within the protection scope of the present disclosure. Therefore, the protection scope of the present disclosure shall be subject to the protection scope of the claims.

What is claimed is:

1. A signal compensation device, comprising:
a balance filter; and
a processor coupled to the balance filter and configured to:
receive an input signal sequence suffering from intersymbol interference (ISI); and
set a first filtering coefficient to perform filter compensation on the received input signal sequence to obtain a first compensation signal sequence, wherein the balance filter is configured to set a balance filtering coefficient to perform the filter compensation on the first compensation signal sequence to obtain a balance compensation result, wherein the balance filtering coefficient is obtained by adjusting, according to a first compensation error received from the processor, a balance filtering coefficient set last time, and
wherein the processor is further configured to:
perform sequence estimation on the balance compensation result;
output the balance compensation result;
obtain the first compensation error by calculation according to a compensation error value obtained last time by calculation and a compensation error value obtained the last but one time by calculation; and
send the first compensation error to the balance filter.

2. The signal compensation device according to claim 1, wherein the processor is further configured to perform subtraction on the compensation error value obtained last time by calculation and the compensation error value obtained the last but one time by calculation, and wherein a difference obtained is the first compensation error.

3. The signal compensation device according to claim 1, wherein the processor is further configured to:
calculate a compensation error value of a currently received balance compensation result when receiving the balance compensation result from the balance filter;
obtain a second compensation error by calculation according to the compensation error value obtained last time by calculation and the compensation error value of the currently received balance compensation result; and
send the second compensation error obtained by calculation to the balance filter.

4. The signal compensation device according to claim 1, wherein the balance filter is further configured to obtain a j^{th} balance filtering coefficient in a manner of b_{j(current)}=b_{j(last time)}+μ*sign (e_{last but one time}−e_{last time}) wherein b_{j(current)} is an obtained coefficient weight of the j^{th} balance filtering coefficient currently set, wherein a value range of j is 0 to L_{b}, wherein L_{b} is a length of the balance filtering coefficient, wherein b_{j(last time)} is a basic coefficient weight of a j^{th} balance filtering coefficient set last time, wherein μ is a coefficient change length of the balance filtering coefficient, wherein (e_{last but one time}−e_{last time}) is the first compensation error, wherein e_{last but one time} is the compensation error value obtained the last but one time by calculation, and wherein e_{last time} is the compensation error value obtained last time by calculation.

5. The signal compensation device according to claim 1, wherein the processor is further configured to send, at an initialization stage, the first filtering coefficient to the balance filter, and wherein the balance filter is further configured to:
receive the first filtering coefficient from the processor;
determine, according to a coefficient weight of the first filtering coefficient, a basic coefficient weight of an initialized balance filtering coefficient; and
obtain an initial value of the balance filtering coefficient according to the basic coefficient weight of the initialized balance filtering coefficient.

6. The signal compensation device according to claim 5, wherein when the received first filtering coefficient from the processor is
$$F ( z ) = {\sum }_{i = 0}^{{L}_{f}} {f}_{i} {z}^{- i} ,$$
the balance filter is further configured to determine the basic coefficient weight of the initialized balance filtering coefficient, according to the coefficient weight of the first filtering coefficient and in a manner of b₀=f₀, and bⱼ=−fᵢ, wherein bⱼ is a basic coefficient weight of a balance filtering coefficient that is initialized, wherein the value range of j is 0 to L_{b}, wherein L_{b} is a length of the balance filtering coefficient, wherein fᵢ is a coefficient weight of a j^{th} first filtering coefficient, wherein a value range of i is 0 to L_{f}, wherein L_{f} is a length of the first filtering coefficient, and wherein z is any complex number.

7. The signal compensation device according to claim 1, wherein the processor is further configured to:
calculate an error result according to a first compensation signal sequence obtained last time and a decision value of the first compensation signal sequence obtained last time;
adjust the first filtering coefficient according to the error result obtained by calculation; and
set an adjusted first filtering coefficient to perform the filter compensation on the currently received input signal sequence.

8. A signal compensation method, comprising:
receiving an input signal sequence suffering from intersymbol interference (ISI);
setting a first filtering coefficient to perform filter compensation on the received input signal sequence to obtain a first compensation signal sequence;
setting a balance filtering coefficient to perform the filter compensation on the first compensation signal sequence to obtain a balance compensation result, wherein the balance filtering coefficient is obtained by adjusting, according to a first compensation error, a balance filtering coefficient set last time, and wherein the first compensation error is obtained by calculation according to a compensation error value obtained last time by calculation and a compensation error value obtained the last but one time by calculation;
performing sequence estimation on the obtained balance compensation result; and
outputting the balance compensation result.

9. The signal compensation method according to claim 8, wherein obtaining the first compensation error comprises performing subtraction on the compensation error value obtained last time by calculation and the compensation error value obtained the last but one time by calculation, and wherein a difference obtained is the first compensation error.

10. The signal compensation method according to claim 8, further comprising:
calculating a compensation error value of the currently received balance compensation result when obtaining the balance compensation result; and
obtaining a second compensation error by calculation according to the compensation error value obtained last time by calculation and the compensation error value of the currently received balance compensation result, wherein the second compensation error adjusts a currently set balance filtering coefficient.

11. The signal compensation method according to claim 8, wherein a j^{th} balance filtering coefficient currently set is obtained in a manner of b_{j(current)}=b_{j(last time)}+μ*sign(e_{last but one time}−e_{last time}), wherein b_{j(current)} is an obtained coefficient weight of the j^{th} balance filtering coefficient that is currently set, wherein a value range of j is 0 to L_{b}, wherein L_{b} is a length of the balance filtering coefficient, wherein b_{j(last time)} is a basic coefficient weight of a j^{th} balance filtering coefficient set last time, wherein μ is a coefficient change length of the balance filtering coefficient, wherein (e_{last but one time}−e_{last time}) is a the first compensation error, wherein e_{last but one time} is the compensation error value obtained the last but one time by calculation, and wherein e_{last time} is the compensation error value obtained last time by calculation.

12. The signal compensation method according to claim 8, further comprising:
determining, at an initialization stage, a basic coefficient weight of an initialized balance filtering coefficient according to a coefficient weight of the first filtering coefficient; and
obtaining an initial value of the balance filtering coefficient according to the basic coefficient weight of the initialized balance filtering coefficient.

13. The signal compensation method according to claim 12, wherein when the first filtering coefficient is
$$F ( z ) = {\sum }_{i = 0}^{{L}_{f}} {f}_{i} {z}^{- i} ,$$
determining the basic coefficient weight of the initialized balance filtering coefficient comprises determining the basic coefficient weight of the initialized balance filtering coefficient in a manner of b₀=f₀, and bⱼ=−fᵢ, wherein bⱼ is a basic coefficient weight of a j^{th} balance filtering coefficient that is initialized, wherein the value range of j is 0 to L_{b}, wherein L_{b} is a length of the balance filtering coefficient, wherein fᵢ is a coefficient weight of a j^{th} first filtering coefficient, wherein a value range of i is 0 to L_{f}, wherein L _{f} is a length of the first filtering coefficient, and wherein z is any complex number.

14. The signal compensation method according to claim 8, further comprising:
calculating an error result according to a first compensation signal sequence obtained last time and a decision value of the first compensation signal sequence obtained last time; and
adjusting the first filtering coefficient according to the error result obtained by calculation, and
wherein setting the first filtering coefficient to perform the filter compensation on the received input signal sequence comprises setting an adjusted first filtering coefficient to perform the filter compensation on the currently received input signal sequence to obtain the first compensation signal sequence.

15. A signal compensation device, comprising:
a signal receiver configured to receive an input signal sequence suffering from intersymbol interference (ISI);
a processor coupled to the signal receiver and configured to:
set a first filtering coefficient to perform filter compensation on the received input signal sequence to obtain a first compensation signal sequence; and
set a balance filtering coefficient to perform the filter compensation on the first compensation signal sequence to obtain a balance compensation result, wherein the balance filtering coefficient is obtained by adjusting, according to a first compensation error, a balance filtering coefficient set last time, and wherein the first compensation error is obtained by calculation according to a compensation error value obtained last time by calculation and a compensation error value obtained the last but one time by calculation; and
a signal transmitter coupled to the signal receiver and the processor and configured to:
perform sequence estimation on the received balance compensation result; and
output the balance compensation result.

16. The signal compensation device according to claim 15, wherein when obtaining the first compensation error, the processor is further configured to perform subtraction on the compensation error value obtained last time by calculation and the compensation error value obtained the last but one time by calculation, and wherein a difference obtained is the first compensation error.

17. The signal compensation device according to claim 15, wherein the processor is further configured to:
calculate a compensation error value of the currently received balance compensation result when obtaining the balance compensation result; and
obtain a second compensation error by calculation according to the compensation error value obtained last time by calculation and the compensation error value of the currently received balance compensation result, wherein the second compensation error adjusts a currently set balance filtering coefficient.

18. The signal compensation device according to claim 15, wherein the processor is further configured to obtain a j^{th} balance filtering coefficient that is currently set, in a manner of b_{j(current)}=b_{j(last time)}+μ*sign(e_{last but one time}−e_{last time}), wherein b_{j(current)} is an obtained coefficient weight of the j^{th} balance filtering coefficient currently set, wherein a value range of j is 0 to L_{b}, wherein L_{b} is a length of the balance filtering coefficient, wherein bⱼ₍_{last time)} is a basic coefficient weight of a j^{th} balance filtering coefficient set last time, wherein μ is a coefficient change length of the balance filtering coefficient, wherein (e_{last but one time}−e_{last time}) is the first compensation error, wherein e_{last but one time} is the compensation error value obtained the last but one time by calculation, and wherein e_{last time} is the compensation error value obtained last time by calculation.

19. The signal compensation device according to claim 15, wherein the processor is further configured to:
determine, at an initialization stage, a basic coefficient weight of an initialized balance filtering coefficient according to a coefficient weight of the first filtering coefficient; and
obtain an initial value of the balance filtering coefficient according to the basic coefficient weight of the initialized balance filtering coefficient.

20. The signal compensation device according to claim 15, wherein the processor is further configured to:
calculate an error result according to a first compensation signal sequence obtained last time and a decision value of the first compensation signal sequence obtained last time;
adjust the first filtering coefficient according to the error result obtained by calculation; and
set an adjusted first filtering coefficient to perform the filter compensation on the currently received input signal sequence to obtain the first compensation signal sequence.
